(19) United States
(12) Patent Application Publication
(10) Pub. No.: US 2024/0421199 A1
(43) Pub. Date: Dec. 19, 2024

(54) SEMICONDUCTOR DEVICE

(71) Applicant: ROHM CO., LTD., Kyoto-shi (JP)

(72) Inventor: Masaki NAGATA, Kyoto-shi (JP)

(73) Assignee: ROHM CO., LTD., Kyoto-shi (JP)

(21) Appl. No.: 18/822,512

(22) Filed: Sep. 3, 2024

Related U.S. Application Data
(63) Continuation of application No. PCT/JP2023/000741, filed on Jan. 13, 2023.

(30) Foreign Application Priority Data
Mar. 14, 2022 (JP) 2022-039009

(51) Int. Cl. H01L 29/40; H01L 27/088; H01L 29/417; H01L 29/423; H01L 29/78

(52) U.S. Cl. CPC H01L 29/404; H01L 27/088; H01L 29/407; H01L 29/41741; H01L 29/4236; H01L 29/7813

(57) ABSTRACT

A semiconductor device includes: a semiconductor layer; a gate trench that is formed in the semiconductor layer and arranged in a mesh pattern in plan view; a field plate trench that is formed in the semiconductor layer and that is surrounded by the gate trench in plan view and separated from the gate trench; an insulation layer formed on the semiconductor layer; a gate electrode arranged in the gate trench; a first field plate electrode arranged in the gate trench below a bottom surface of the gate electrode; a second field plate electrode arranged in the field plate trench; and a source electrode formed on the insulation layer. The first field plate electrode and the second field plate electrode are electrically connected to the source electrode.

### CROSS-REFERENCE TO RELATED APPLICATIONS

The present application is a bypass continuation of International Patent Application No. PCT/JP2023/000741, filed on Jan. 13, 2023, which claims priority to Japanese Patent Application No. 2022-039009 filed on Mar. 14, 2022, the entire disclosures of these applications are incorporated herein by reference.

### BACKGROUND

### 1. Field

The present disclosure relates to a semiconductor device.

### 2. Description of Related Art

Japanese Laid-Open Patent Publication No. 2020-072158 discloses a MISFET having a trench gate structure. The trench gate structure includes a gate trench, an insulation layer, a bottom side electrode, and an open side electrode. Japanese Laid-Open Patent Publication No. 2020-072158 describes that when reference voltage is applied to the bottom side electrode and gate voltage is applied to the open side electrode, the switching speed is increased without decreasing the breakdown voltage of the MISFET.

### BRIEF DESCRIPTION OF THE DRAWINGS

FIG. 1 is a schematic plan view of an exemplary semiconductor device in accordance with one embodiment.

FIG. 2 is a schematic cross-sectional view of a gate trench taken along line F2-F2 in FIG. 1.

FIG. 3 is an enlarged plan view of the semiconductor device illustrated in FIG. 1.

FIG. 4 is a schematic cross-sectional view of a field plate trench taken along line F4-F4 in FIG. 3.

FIG. 5 is a schematic plan view showing a semiconductor device of a comparative example.

FIG. 6 is a schematic cross-sectional view showing a field plate trench of a semiconductor device in a first modified example.

FIG. 7 is a schematic plan view of an exemplary semiconductor device in a second modified example.

FIG. 8 is a schematic plan view of an exemplary semiconductor device in a third modified example.

FIG. 9 is an enlarged plan view of the semiconductor device illustrated in FIG. 8.

FIG. 10 is a schematic plan view of an exemplary semiconductor device in a fourth modified example.

### DETAILED DESCRIPTION

Several embodiments of a semiconductor device in accordance with the present disclosure will now be described with reference to the accompanying drawings. Elements in the figures are illustrated for simplicity and clarity and have not necessarily been drawn to scale. To aid understanding, hatching lines may not be shown in the cross-sectional drawings. The accompanying drawings illustrate exemplary embodiments in accordance with the present disclosure and are not intended to limit the present disclosure.

This detailed description provides a comprehensive understanding of exemplary methods, apparatuses, and/or systems in accordance with the present disclosure. This detailed description is illustrative and is not intended to limit embodiments of the present disclosure or the application and use of the embodiments.

### Mesh Arrangement of Gate Trench

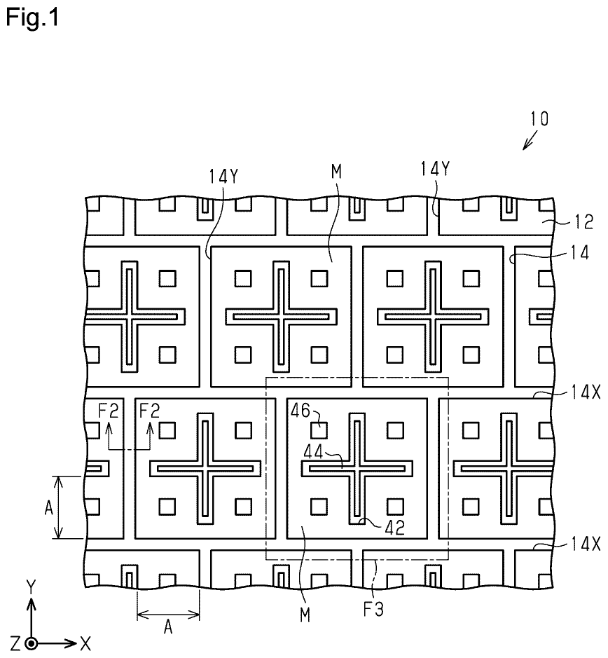

FIG. 1 is a schematic plan view of an exemplary semiconductor device 10 in accordance with one embodiment. In this specification, the X-axis, Y-axis, and Z-axis are orthogonal to one another as shown in FIG. 1. The term “plan view” as used in this specification is a view of the semiconductor device 10 taken in the Z-axis direction. Unless otherwise indicated, the term “plan view” will refer to a view taken from above along the Z-axis of the semiconductor device 10.

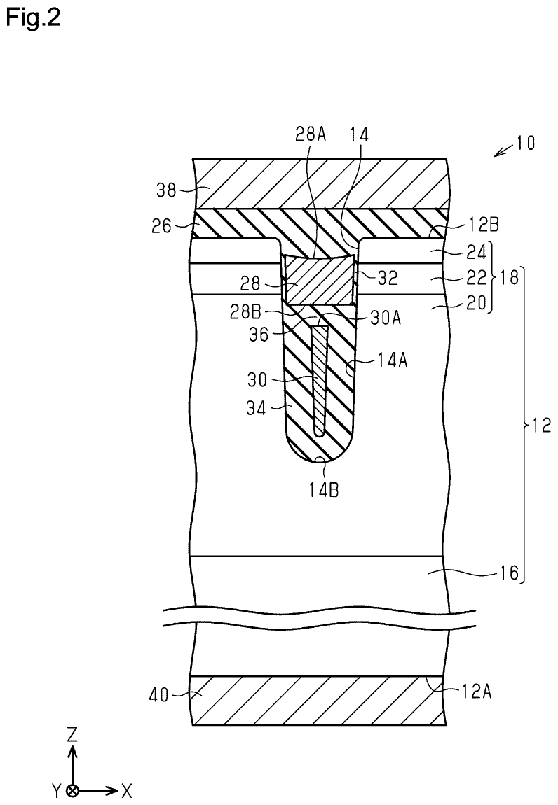

The semiconductor device 10 is, for example, a metal insulator semiconductor field effect transistor (MISFET) having a trench gate structure. The semiconductor device 10 includes a semiconductor layer 12 and a gate trench 14 formed in the semiconductor layer 12. FIG. 1 shows an active region of the semiconductor device 10. In one example, the semiconductor layer 12 is composed of silicon (Si). The semiconductor layer 12 includes a first surface 12A, which is orthogonal to the Z-axis shown in FIG. 1, and a second surface 12B opposite to the first surface 12A (refer to FIG. 2).

The gate trench 14 is formed in the semiconductor layer 12 and arranged in a mesh pattern in plan view. The gate trench 14 includes lateral gate trench portions 14X, which extend in the X-axis direction in plan view and have a width in the Y-axis direction, and longitudinal gate trench portions 14Y, which extend in the Y-axis direction in plan view and have a width in the X-axis direction. The lateral gate trench portions 14X and the longitudinal gate trench portions 14Y interconnect so that the gate trench 14 has the mesh pattern shown in FIG. 1. In this specification, the Y-axis direction will be referred to as the first direction, and the X-axis direction will be referred to as the second direction. Accordingly, the second direction is orthogonal to the first direction.

The semiconductor layer 12 may include mesh cells M surrounded by the gate trench 14, which is arranged in a mesh pattern in plan view. In one example, the mesh cells M may each be square in plan view. In the example of FIG. 1, the mesh cells M are aligned in the X-axis direction and arranged in an offset manner in the Y-axis direction. As a result, the lateral gate trench portions 14X and the longitudinal gate trench portions 14Y form T intersections and do not intersect in a cross-like manner. Such a mesh pattern is advantageous in the manufacturing process of the semiconductor device 10. In another example, the mesh cells M may be aligned in both the X-axis direction and the Y-axis direction.

### Detail of Gate Trench

With reference to FIG. 2, the gate trench 14 of the semiconductor device 10 will now be described in detail. FIG. 2 is a schematic cross-sectional view of the semiconductor device 10 taken along line F2-F2 in FIG. 1. FIG. 2 shows a cross section of a longitudinal gate trench portion 14Y taken in a width direction (X-axis direction). Although not shown, it is to be understood that a cross section of a lateral gate trench portion 14X taken in a width direction (Y-axis direction) will be the same as that shown in FIG. 2 and differ only in that the cross section will be rotated by 90° in an XY plane.

The semiconductor layer 12 may include the semiconductor substrate 16, which includes the first surface 12A of the semiconductor layer 12, and an epitaxial layer 18, which is formed on the semiconductor substrate 16 and includes the second surface 12B of the semiconductor layer 12. The semiconductor substrate 16 may be a Si substrate. The semiconductor substrate 16 corresponds to a drain region of a MISFET. The epitaxial layer 18 may be a Si layer that is epitaxially grown on a Si substrate. The epitaxial layer 18 may include a drift region 20, a body region 22 formed on the drift region 20, and a source region 24 formed on the body region 22. The source region 24 may include the second surface 12B of the semiconductor layer 12.

The drain region (semiconductor substrate 16) may be an n-type region containing n-type impurities. The drain region (semiconductor substrate 16) may have an n-type impurity concentration in a range from 1×10¹⁸ cm⁻³ to 1×10²⁰ cm⁻³, inclusive. The drain region (semiconductor substrate 16) may have a thickness in a range from 50 μm to 450 μm, inclusive.

The drift region 20 may be an n-type region containing n-type impurities at a lower concentration than the drain region (semiconductor substrate 16). The drift region 20 may have an n-type impurity concentration in a range from 1×10¹⁵ cm⁻³ to 1×10¹⁸ cm⁻³. The drift region 20 may have a thickness in a range from 1 μm to 25 μm, inclusive.

The body region 22 may be a p-type region containing p-type impurities. The body region 22 may have a p-type impurity concentration in a range from 1×10¹⁶ cm⁻³ to 1×10¹⁸ cm⁻³, inclusive. The body region 22 may have a thickness in a range from 0.2 μm to 1.0 μm, inclusive.

The source region 24 may be an n-type region containing n-type impurities at a higher concentration than the drift region 20. The source region 24 may have an n-type impurity concentration in a range from 1×10¹⁹ cm⁻³ to 1×10²¹ cm⁻³, inclusive. The source region 24 may have a thickness in a range from 0.1 μm to 1 μm, inclusive.

In the present disclosure, n-type is also referred to as a first conductivity type, and p-type is also referred to as a second conductivity type. The n-type impurities may be, for example, phosphorus (P), arsenic (As), or the like. The p-type impurities may be, for example, boron (B), aluminum (Al), or the like.

The gate trench 14 opens in the second surface 12B of the semiconductor layer 12 and has a depth in the Z-axis direction. The gate trench 14 extends through the source region 24 and the body region 22 of the semiconductor layer 12 to the drift region 20. The gate trench 14 includes a side wall 14A and a bottom wall 14B. The bottom wall 14B is adjacent to the drift region 20. The gate trench 14 may have a depth in a range from 1 μm to 10 μm, inclusive.

The side wall 14A of the gate trench 14 may extend in a direction orthogonal to the second surface 12B of the semiconductor layer 12 (Z-axis direction) or be inclined relative to the second surface 12B. In one example, the side wall 14A may be inclined relative to the Z-axis direction so that the width of the gate trench 14 decreases toward the bottom wall 14B. Further, the bottom wall 14B of the gate trench 14 does not necessarily have to be flat and may be partially or entirely curved.

The semiconductor device 10 further includes an insulation layer 26 formed on the semiconductor layer 12. In one example, the insulation layer 26 may be formed by a film of silicon oxide (SiO₂). In addition to or instead of the silicon oxide film, the insulation layer 26 may include a layer composed of an insulation material that differs from SiO₂, for example, silicon nitride (SiN).

The semiconductor device 10 further includes a gate electrode 28 and a first field plate electrode 30 that are arranged in the gate trench 14. The gate electrode 28 is an electrode to which gate voltage is applied, and the first field plate electrode 30 is an electrode to which reference voltage (or source voltage) is applied. In this specification, the trench in which the gate electrode 28 is arranged will be referred to as the gate trench 14.

The gate electrode 28 includes an upper surface 28A, which is covered by the insulation layer 26, and a bottom surface 28B opposite to the upper surface 28A. The first field plate electrode 30 is arranged in the gate trench 14 below the bottom surface 28B of the gate electrode 28 (between bottom surface 28B of gate electrode 28 and bottom wall 14B of gate trench 14). At least part of the bottom surface 28B of the gate electrode 28 faces the first field plate electrode 30 with the insulation layer 26 located in between.

The upper surface 28A of the gate electrode 28 may be located below the second surface 12B of the semiconductor layer 12. The upper surface 28A and the bottom surface 28B of the gate electrode 28 may be flat or curved. Further, the gate electrode 28 may have a uniform width overall in the Z-axis direction, but the width need not be uniform overall. For example, the bottom portion of the gate electrode 28 including the bottom surface 28B may have a smaller width than other portions.

The first field plate electrode 30 is surrounded by the insulation layer 26 (lower insulator 34, described later). The first field plate electrode 30 may have a smaller width than the gate electrode 28. When the first field plate electrode 30 has a relatively small width, the insulation layer 26 (lower insulator 34), which surrounds the first field plate electrode 30, will have a relatively large thickness. This mitigates electric field concentration in the gate trench 14.

The gate electrode 28 may be positioned so that the interface of the drift region 20 and the body region 22 is not located below the bottom surface 28B of the gate electrode 28 in the Z-axis direction. The interface of the drift region 20 and the body region 22 may be located at the same position as the bottom surface 28B of the gate electrode 28 or upward from the bottom surface 28B in the Z-axis direction.

In one example, the gate electrode 28 and the first field plate electrode 30 are composed of polysilicon that is conductive.

The insulation layer 26 may include a gate insulator 32 that is located between the gate electrode 28 and the semiconductor layer 12 and covers the side wall 14A of the gate trench 14. The gate insulator 32 separates the gate electrode 28 and the semiconductor layer 12. A predetermined voltage is applied to the gate electrode 28 to form a channel in the p-type body region 22, which is adjacent to the gate insulator 32. The semiconductor device 10 controls the flow of electrons in the Z-axis direction through the channel between the n-type source region 24 and the n-type drift region 20.

The insulation layer 26 may further include the lower insulator 34 that is located between the first field plate electrode 30 and the semiconductor layer 12 and covers the side wall 14A and the bottom wall 14B of the gate trench 14. The lower insulator 34 on the side wall 14A of the gate trench 14 may be thicker than the gate insulator 32. The insulation layer 26 may further include an intermediate insulator 36 that is located between the upper surface 30A of the first field plate electrode 30 and the bottom surface 28B of the gate electrode 28.

The semiconductor device 10 further includes a source electrode 38 formed on the insulation layer 26. In the semiconductor device 10, the source electrode 38 is not directly formed on the source region 24 of the semiconductor layer 12, and is formed on the insulation layer 26. This is advantageous in that the effect of voltage fluctuation of the source region 24 will be limited.

The first field plate electrode 30 may be coupled to the source electrode 38 in a region that is not illustrated in the drawings (e.g., peripheral region surrounding active region shown in FIG. 1). This electrically connects the first field plate electrode 30 to the source electrode 38. The source electrode 38 may be composed of at least one of titanium (Ti), nickel (Ni), gold (Au), silver (Ag), copper (Cu), aluminum (Al), a Cu alloy, and an Al alloy.

The semiconductor device 10 may further include a drain electrode 40 formed on the first surface 12A of the semiconductor layer 12. The drain electrode 40 is adjacent to and electrically connected to the drain region (semiconductor substrate 16). The drain electrode 40 may be composed of at least one of Ti, Ni, Au, Ag, Cu, Al, a Cu alloy, and an Al alloy.

### Elements Arranged in Mesh Cell

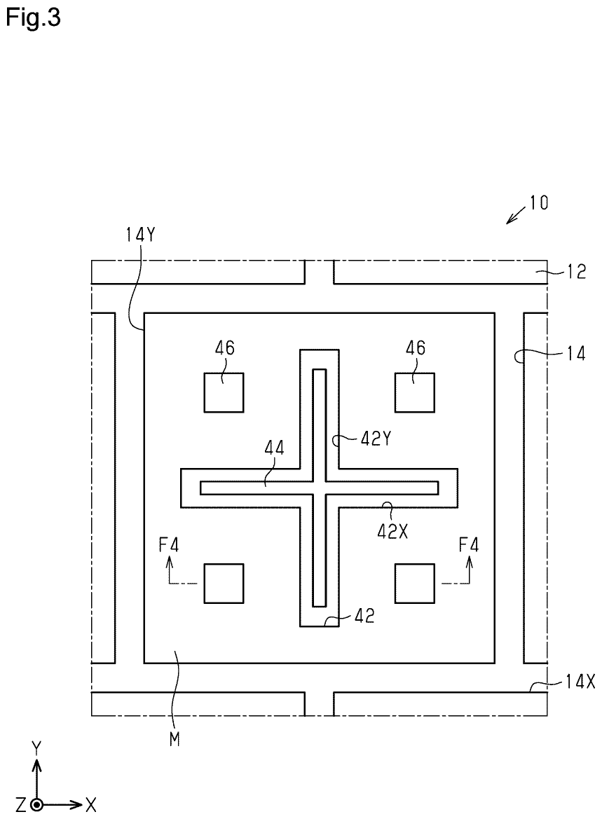

With reference to FIG. 3, the elements arranged in the mesh cells M illustrated in FIG. 1 will now be described. FIG. 3 is an enlarged plan view of the semiconductor device 10 illustrated in FIG. 1. FIG. 3 shows region F3 that is encompassed by single-dashed lines in FIG. 1 and includes one of the mesh cells M surrounded by the gate trench 14. The description hereafter will also apply to the other mesh cells M.

The semiconductor device 10 further includes a field plate trench 42 formed in the semiconductor layer 12. The field plate trench 42 may be one of multiple field plate trenches 42 respectively arranged in the mesh cells M included in the semiconductor layer 12. Each field plate trench 42 is surrounded by the gate trench 14 and separated from the gate trench 14. Thus, the field plate trench 42 and the gate trench 14 are not interconnected. In one example, the field plate trench 42 in each mesh cell M may be cross-shaped in plan view. In the example of FIG. 1, the field plate trench 42 includes lateral field plate trench portions 42X, which extend in the X-axis direction in plan view and have a width in the Y-axis direction, and the longitudinal field plate trench portions 42Y, which extend in the Y-axis direction in plan view and have a width in the X-axis direction. The lateral field plate trench portions 42X intersect the longitudinal field plate trench portions 42Y in the central part of each mesh cell M so that the field plate trench 42 has a cross-shaped pattern such as that shown in FIG. 3.

As described above, the gate trench 14 includes the longitudinal gate trench portions 14Y extending in the Y-axis direction. Each field plate trench 42 is surrounded by the gate trench 14. Thus, the longitudinal field plate trench portions 42Y and the longitudinal gate trench portions 14Y are arranged alternately in the X-axis direction. In other words, the gate trench 14 and the field plate trenches 42 both include portions extending in the Y-axis direction, with such portions being arranged alternately in the X-axis direction, which is orthogonal to the Y-axis direction.

Further, as described above, the gate trench 14 includes the lateral gate trench portions 14X extending in the X-axis direction. Each field plate trench 42 is surrounded by the gate trench 14 in plan view. Thus, the lateral field plate trench portions 42X and the lateral gate trench portions 14X are arranged alternately in the Y-axis direction. In other words, the gate trench 14 and the field plate trenches 42 both include portions extending in the X-axis direction, with such portions being arranged alternately in the Y-axis direction, which is orthogonal to the X-axis direction.

The semiconductor device 10 includes first contact plugs 44 and second contact plugs 46. The first contact plugs 44 are arranged to overlap the field plate trenches 42 in plan view. In one example, each first contact plug 44 may be arranged in the corresponding field plate trench 42 in plan view. The second contact plugs 46 are arranged between the gate trench 14 and each field plate trench 42 in plan view.

In the example of FIG. 1, the first contact plug 44 may be cross-shaped in plan view in the same manner as the field plate trench 42. The first contact plugs 44 are not limited to the shape and arrangement illustrated in the example of FIG. 1 and may take other shapes and arrangements. For example, one or more rectangular first contact plugs 44 may be arranged in the field plate trench 42, which is cross-shaped in plan view.

In the example of FIG. 1, four second contact plugs 46 are arranged in point symmetry with respect to the center of each mesh cell M. The second contact plugs 46 may each be square in plan view. The second contact plugs 46 are not limited to the shape and arrangement illustrated in the example of FIG. 1 and may take other shapes and arrangements. For example, the second contact plugs 46 may be arranged closer to the field plate trench 42 than the example of FIG. 1.

Each of the first contact plugs 44 and the second contact plugs 46 may be composed of any metal material. In one example, the contact plugs 44 and 46 may be composed of at least one of tungsten (W), Ti, and nitride titanium (TiN).

### Details of Field Plate Trench

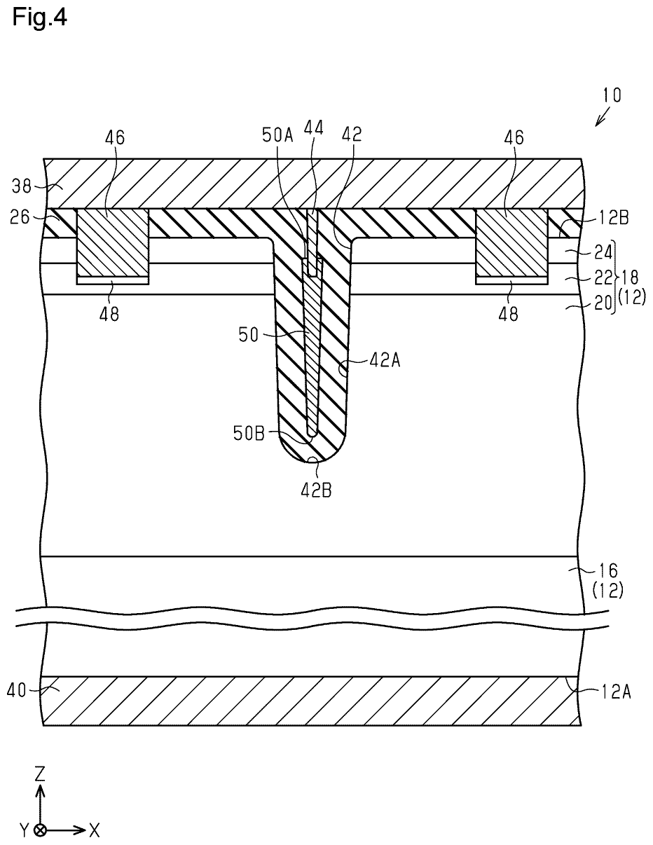

With reference to FIG. 4, the field plate trench 42 of the semiconductor device 10 will now be described. FIG. 4 is a schematic cross-sectional view of the semiconductor device 10 taken along line F4-F4 in FIG. 3. FIG. 4 shows a cross section taken along the width direction (X-axis direction) of the longitudinal field plate trench portion 42Y Although not shown in the drawings, a cross section taken along the width direction (Y-axis direction) of the lateral field plate trench portion 42X will be the same as that shown in FIG. 4 except in that the cross section will be rotated by 90° in an XY plane. The cross section of FIG. 4 shows two second contact plugs 46.

The semiconductor layer 12 including the field plate trench 42 is the same as that described with reference to FIG. 2. The semiconductor layer 12 further includes contact regions 48 arranged adjacent to the second contact plugs 46.

The contact regions 48 may be p-type regions containing P-type impurities. The contact regions 48 may have a p-type impurity concentration in a range from 1×10¹⁹ cm⁻³ to 1×10²¹ cm⁻³, inclusive, which is higher than that of the body region 22.

The field plate trench 42 opens in the second surface 12B of the semiconductor layer 12 and has a depth in the Z-axis direction. The field plate trench 42 extends through the source region 24 of the semiconductor layer 12 and the body region 22 to the drift region 20. The field plate trench 42 includes a side wall 42A and a bottom wall 42B. The bottom wall 42B is adjacent to the drift region 20. The field plate trench 42 may have a depth in a range from 1 μm to 10 μm, inclusive.

The side wall 42A of the field plate trench 42 may, but does not have to, extend in a direction orthogonal to the second surface 12B of the semiconductor layer 12 (Z-axis direction). In one example, the side wall 42A may be inclined relative to the Z-axis direction so that the width of the field plate trench 42 decreases toward the bottom wall 42B. Further, the bottom wall 42B of the field plate trench 42 does not necessarily have to be flat and may be partially or entirely curved.

The field plate trench 42 and the gate trench 14 may have the same width or different widths. Further, the field plate trench 42 and the gate trench 14 may have the same depth or different depths. For example, the field plate trench 42 may have a greater width than the gate trench 14, and the field plate trench 42 may have a greater depth than the gate trench 14.

The semiconductor device 10 further includes a second field plate electrode 50 arranged in the field plate trench 42. A reference voltage (or source voltage) may be applied to the second field plate electrode 50. In the present specification, a trench in which the second field plate electrode 50 is arranged is referred to as the field plate trench 42. A trench in which the gate electrode 28 (refer to FIG. 2) is not arranged may also be referred to as the field plate trench 42.

The second field plate electrode 50 includes an upper surface 50A, which is covered by the insulation layer 26, and a bottom surface 50B opposite to the upper surface 50A. The upper surface 50A of the second field plate electrode 50 may be located below the second surface 12B of the semiconductor layer 12. The second field plate electrode 50 is surrounded by the insulation layer 26.

The upper surface 50A and the bottom surface 50B of the second field plate electrode 50 may be flat or curved. Further, the second field plate electrode 50 may have a uniform width overall in the Z-axis direction, but the width need not be uniform. For example, the second field plate electrode 50 may have a width that becomes smaller toward the bottom wall 42B of the field plate trench 42. Further, the second field plate electrode 50 may have a smaller width than the gate electrode 28 (refer to FIG. 2). In one example, the second field plate electrode 50 is composed of polysilicon that is conductive.

The first contact plug 44 is configured to couple the second field plate electrode 50 to the source electrode 38. The first contact plug 44 extends through the insulation layer 26 between the upper surface 50A of the second field plate electrode 50 and the source electrode 38. Thus, the second field plate electrode 50 is electrically connected to the source electrode 38. In one example, the first contact plug 44 may have a smaller width than the second field plate electrode 50.

The second contact plugs 46 are configured to couple the semiconductor layer 12 to the source electrode 38. The second contact plugs 46 are in contact with the contact regions 48 formed in the semiconductor layer 12. The second contact plugs 46 electrically connect the corresponding contact regions 48 to the source electrode 38. The second contact plugs 46 extend through the insulation layer 26 between the semiconductor layer 12 and the source electrode 38. The second contact plugs 46 extend through the source region 24 in the semiconductor layer 12 to the body region 22.

### Operation

The operation of the semiconductor device 10 in accordance with the present embodiment will now be described.

The semiconductor device 10 of the present embodiment includes the gate trench 14, which is arranged in a mesh pattern in plan view, and the field plate trenches 42, which are surrounded by the gate trench 14 in plan view and separated from the gate trench 14. The gate electrode 28 and the first field plate electrode 30 are arranged in the gate trench 14. The second field plate electrode 50 is arranged in each field plate trench 42. The first field plate electrode 30 and each second field plate electrode 50 are electrically connected to the source electrode 38.

The first field plate electrode 30, which is electrically connected to the source electrode 38, is arranged in the gate trench 14. This mitigates local electric field concentration in the semiconductor layer 12 around the gate trench 14. In the same manner, the second field plate electrode 50, which is electrically connected to the source electrode 38, is arranged in each field plate trench 42. This mitigates local electric field concentration in the semiconductor layer 12 around the field plate trenches 42. Accordingly, the arrangement of the field plate trenches 42 in addition to the gate trench 14 increases the breakdown voltage of the semiconductor device 10.

Further, the gate electrode 28 is not arranged in the field plate trenches 42. Thus, the field plate trenches 42 limit increases in the gate-drain parasitic capacitance and the gate-source parasitic capacitance, while increasing the breakdown voltage of the semiconductor device 10.

### Comparative Example

The gate-drain parasitic capacitance and the gate-source parasitic capacitance of the semiconductor device 10 will now be described with reference to a comparative example.

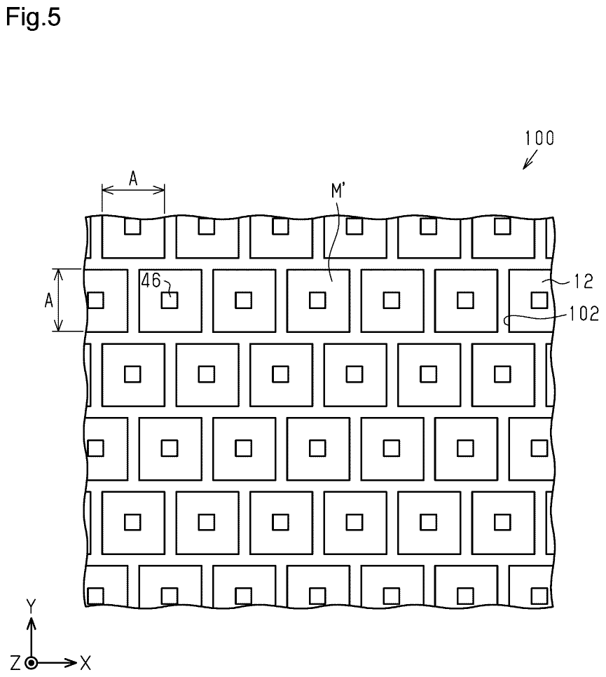

FIG. 5 is a schematic plan view showing a semiconductor device 100 of the comparative example. The semiconductor device 100 includes a gate trench 102 arranged in a mesh pattern in plan view in the same manner as the gate trench 14 of the semiconductor device 10. The semiconductor device 100 does not have a trench including only an electrode to which reference voltage (or source voltage) is applied like the field plate trench 42 of the semiconductor device 10. Thus, the gate trench 102 has a relatively high density. In other words, in the semiconductor device 100, each mesh cell M′ surrounded by the gate trench 102 has sides, each having a relatively small dimension (indicated by A). The second contact plug 46 may be arranged in each mesh cell M′.

The gate electrode 28 and the first field plate electrode 30, which are similar to those shown in FIG. 2, are arranged in the gate trench 102. The first field plate electrode 30, which is arranged in the gate trench 102, surrounds the mesh cells M′ and increases the breakdown voltage of the semiconductor device 100. The gate electrode 28 is also arranged in the gate trench 102. Thus, in the semiconductor device 100, the gate-drain parasitic capacitance and the gate-source parasitic capacitance are relatively large.

In this respect, in the semiconductor device 10 shown in FIG. 1, the distance of A between the gate trench 14 and the field plate trench 42, which extend parallel to each other, allows the breakdown voltage to be about the same as that of the semiconductor device 100 shown in FIG. 5. This is because the first field plate electrode 30 in the gate trench 14 and the second field plate electrode 50 in each field plate trench 42 surround a region of which the area is about the same as that of each mesh cell M′. The gate electrode 28 is not arranged in the field plate trench 42 of the semiconductor device 10. Thus, the gate-drain parasitic capacitance and the gate-source parasitic capacitance in the semiconductor device 10 is smaller than that of the semiconductor device 100.

### Advantages

The semiconductor device 10 of the present embodiment has the advantages described below.

(1) The semiconductor device 10 includes the gate trench 14, which is arranged in a mesh pattern in plan view, and the field plate trenches 42, which are surrounded by the gate trench 14 and separated from the gate trench 14. The gate electrode 28 and the first field plate electrode 30 are arranged in the gate trench 14. The second field plate electrode 50 is arranged in each field plate trench 42. The first field plate electrode 30 and each second field plate electrode 50 are electrically connected to the source electrode 38. This limits increases in the gate-drain parasitic capacitance and the gate-source parasitic capacitance, while increasing the breakdown voltage of the semiconductor device 10.

(2) The semiconductor device 10 may further include the first contact plugs 44, each configured to couple the corresponding second field plate electrode 50 to the source electrode 38. The first contact plug 44 extends through the insulation layer 26 between the upper surface 50A of the second field plate electrode 50 and the source electrode 38. The first contact plug 44, which extends through the insulation layer 26, is used to couple the second field plate electrode 50 to the source electrode 38. This limits decreases in the breakdown voltage of the semiconductor device 10, and ensures electrical connection between the second field plate electrode 50 and the source electrode 38.

(3) The field plate trench 42 may be cross-shaped in plan view. This mitigates local electric field concentration at the mesh cells M so that the electric field becomes relatively uniform.

(4) The semiconductor layer 12 includes the contact regions 48 of the first conductivity type, and the contact regions 48 are in contact with the second contact plugs 46. This ensures electrical connection between the source electrode 38 and the semiconductor layer 12 through the second contact plug 46.

### First Modified Example

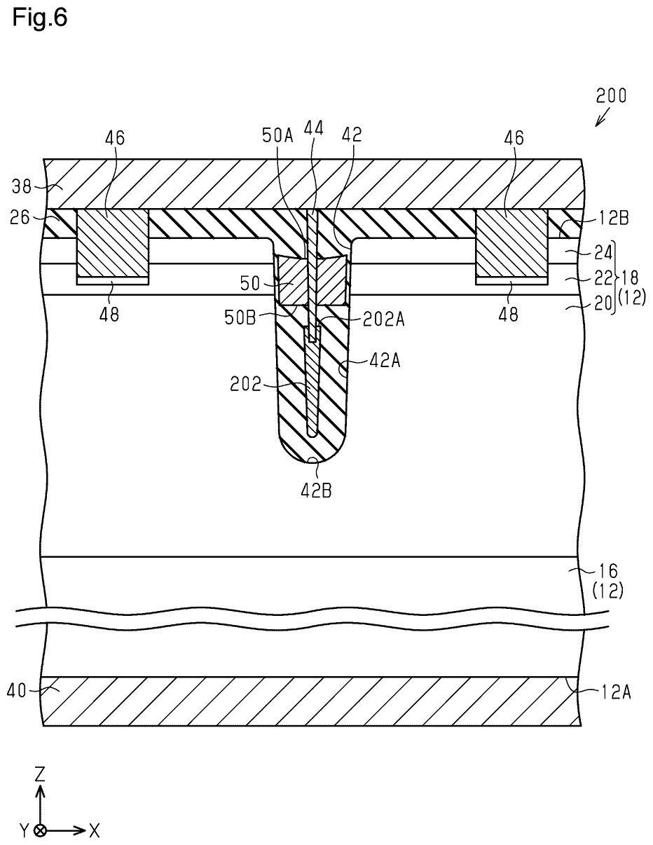

FIG. 6 is a schematic cross-sectional view showing the field plate trench 42 of a semiconductor device 200 in a first modified example. In FIG. 6, same reference characters are given to those elements that are the same as the corresponding elements in the semiconductor device 10. Components that are the same as the corresponding components of the semiconductor device 10 will not be described in detail.

The semiconductor device 200 further includes third field plate electrodes 202. Each third field plate electrode 202 is arranged in a corresponding one of the field plate trenches 42 below the bottom surface 50B of the second field plate electrode 50. More specifically, the third field plate electrode 202 is arranged between the bottom surface 50B of the second field plate electrode 50 and the bottom wall 42B of the field plate trench 42. The second field plate electrode 50 and the third field plate electrode 202 of the semiconductor device 200 respectively have the same shape as the gate electrode 28 and the first field plate electrode 30 shown in FIG. 2.

In the semiconductor device 200, the first contact plug 44 is further configured to couple the corresponding third field plate electrode 202 to the source electrode 38. The first contact plug 44 extends through the corresponding second field plate electrode 50 to the third field plate electrode 202. The first contact plug 44 extends downward from an upper surface 202A of the third field plate electrode 202.

In the semiconductor device 200, the second field plate electrode 50 and the third field plate electrode 202 are electrically connected to the source electrode 38. This increases the breakdown voltage in the same manner as the semiconductor device 10. Further, the second field plate electrode 50 and the third field plate electrode 202 in each field plate trench 42 may be formed through a manufacturing process similar to that of the gate electrode 28 and the first field plate electrode 30 in the gate trench 14. Accordingly, the semiconductor device 200 may be manufactured through a relatively simple process.

### Second Modified Example

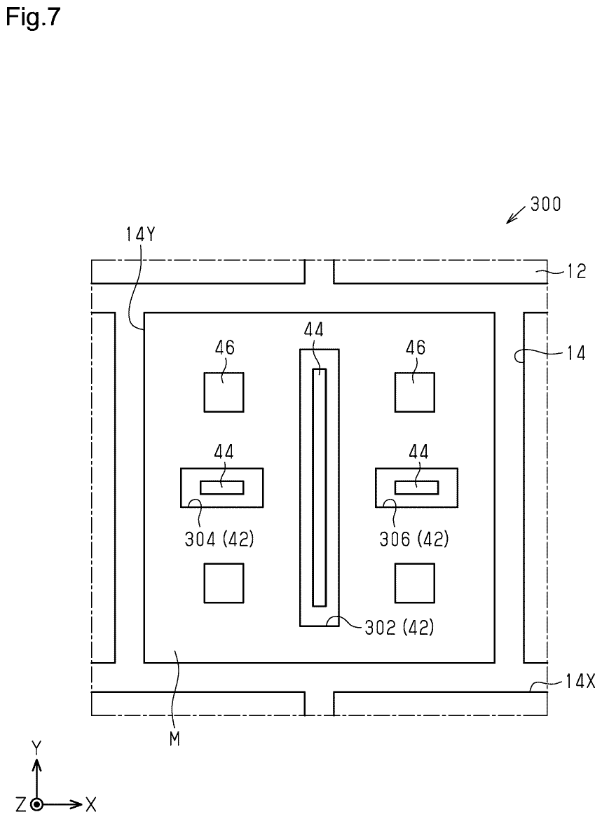

FIG. 7 is a schematic plan view of a semiconductor device 300 in a second modified example. In FIG. 7, same reference characters are given to those elements that are the same as the corresponding elements in the semiconductor device 10. Components that are the same as the corresponding components of the semiconductor device 10 will not be described in detail. FIG. 7 shows a region including a single mesh cell M surrounded by the gate trench 14.

In the semiconductor device 300, each field plate trench 42 includes a first trench 302, which extends in the Y-axis direction in plan view, and a second trench 304 and third trench 306, which extend in the X-axis direction and are separated from the first trench 302. The first trench 302 extends between the second trench 304 and the third trench 306 in plan view.

In this manner, the field plate trench 42 may include the trenches 302, 304, and 306, which are independent from one another in each mesh cell M. In this case, the first contact plugs 44 may be arranged to overlap the trenches 302, 304, and 306 in plan view.

The electric field distribution in the mesh cells M may be changed in accordance with the shape and arrangement of the field plate trench 42 to obtain the desired breakdown voltage or operational characteristics of the semiconductor device 300.

### Third Modified Example

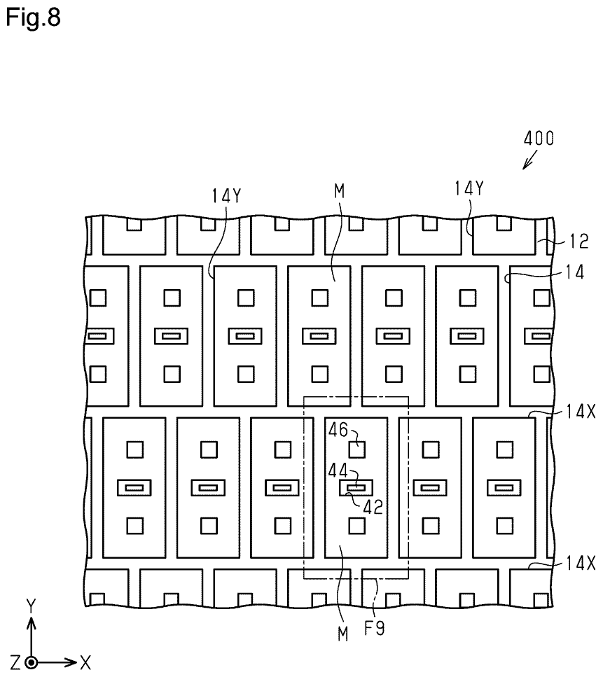

FIG. 8 is a schematic plan view of a semiconductor device 400 in a third modified example. In FIG. 8, same reference characters are given to those elements that are the same as the corresponding elements in the semiconductor device 10. Components that are the same as the corresponding components of the semiconductor device 10 will not be described in detail.

In the semiconductor device 400, the mesh cells M, which are surrounded by the gate trench 14 that is arranged in a mesh pattern, are rectangular in plan view. In the example of FIG. 8, each mesh cell M has a dimension in the X-axis direction that is smaller than that in the Y-axis direction.

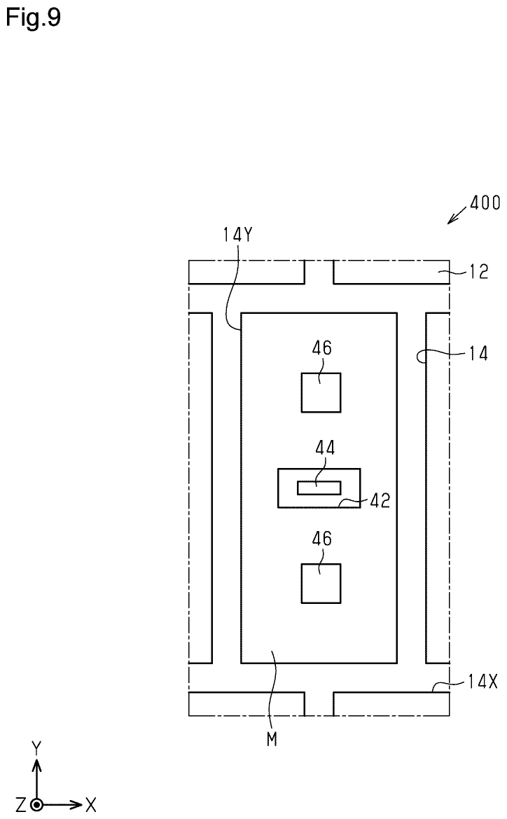

FIG. 9 is an enlarged plan view of the semiconductor device 400 illustrated in FIG. 8. FIG. 9 shows region F9 that is encompassed by single-dashed lines in FIG. 8 and includes one of the mesh cells M surrounded by the gate trench 14.

In each mesh cell M of the semiconductor device 400, the field plate trench 42 is rectangular in plan view. In the example of FIG. 9, the field plate trench 42 extends in the X-axis direction in plan view and has a width in the Y-axis direction. That is, the longitudinal direction of the field plate trench 42 is the X-axis direction. The field plate trench 42 is arranged in the central part of the mesh cell M.

The first contact plugs 44 are arranged to overlap the field plate trench 42 in plan view. In the example of FIG. 9, the first contact plug 44 extends in the X-axis direction in plan view and has a width in the Y-axis direction in the same manner as the field plate trench 42.

The second contact plugs 46 are arranged between the gate trench 14 and the field plate trench 42 in plan view. In the example of FIG. 9, the second contact plugs 46 are each square and arranged at the middle between the gate trench 14 and the field plate trench 42 in the Y-axis direction. Each mesh cell M includes two second contact plugs 46.

The semiconductor device 400 including the rectangular mesh cells M illustrated in FIGS. 8 and 9 limits increases in the gate-drain parasitic capacitance and the gate-source parasitic capacitance, while increasing the breakdown voltage.

### Fourth Modified Example

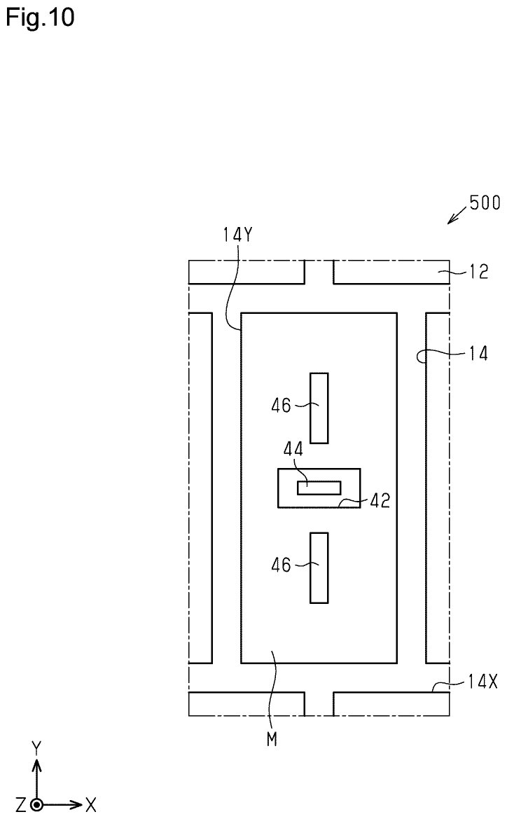

FIG. 10 is a schematic plan view of a semiconductor device 500 in a fourth modified example. In FIG. 10, same reference characters are given to those elements that are the same as the corresponding elements in the semiconductor device 10. Components that are the same as the corresponding components of the semiconductor device 10 will not be described in detail. FIG. 10 shows a region including one of the mesh cells M surrounded by the gate trench 14.

In the semiconductor device 500, the second contact plugs 46 extend in the Y-axis direction and have a width in the X-axis direction. That is, the longitudinal direction of the second contact plugs 46 is the Y-axis direction. In the example of FIG. 10, the line-shaped second contact plugs 46 are arranged between the gate trench 14 and the field plate trench 42, closer to the field plate trench 42. Each mesh cell M includes two second contact plugs 46.

In this manner, the electric field distribution in the mesh cells M may be changed in accordance with the shape and arrangement of the second contact plugs 46 to obtain the desired breakdown voltage or operational characteristics of the semiconductor device 500.

### Other Modified Examples

The above-described embodiments and modified examples may be modified as described below.

The mesh cells M do not have to be rectangular in plan view. For example, the mesh cells M may be triangular or hexagonal in plan view.

The conductivity type of each region may be reversed in the semiconductor layer 12. That is, a p-type region may be changed to an n-type region, and an n-type region may be changed to a p-type region.

The above embodiment and the modified examples described below may be combined as long as there is no technical contradiction.

In this specification, “at least one of A and B” should be understood to mean “only A, only B, or both A and B.”

In this specification, the word “on” includes the meaning of “above” in addition to the meaning of “on” unless otherwise described in the context. Accordingly, the phrase of “first layer formed on second layer” may mean that the first layer is formed directly contacting the second layer in one embodiment and that the first layer is arranged above the second layer without contacting the second layer in another embodiment. Thus, the word “on” will also allow for a structure in which another layer is arranged between the first layer and the second layer.

The terms used in this specification to indicate directions such as vertical, horizontal, upward, downward, up, down, forward, rearward, side, left, right, front, and back will be attributed to specific directions of the described and illustrated device. In this disclosure, a variety of alternative directions may be available for any given direction. Thus, directional terms should not be construed narrowly.

For example, the Z-axis direction as referred to in this specification does not necessarily have to be the vertical direction and does not necessarily have to fully coincide with the vertical direction. For example, the X-axis direction may be the vertical direction. Alternatively, the Y-axis direction may be the vertical direction.

### CLAUSES

Technical concepts that can be understood from each of the above embodiments and modified examples will now be described. Reference characters used in the described embodiment are added to corresponding elements in the clauses to aid understanding without any intention to impose limitations to these elements. The reference characters are given as examples to aid understanding and not intended to limit elements to the elements denoted by the reference characters.

### [Clause 1]

A semiconductor device, including:
a semiconductor layer (12);
a gate trench (14) formed in the semiconductor layer (12) and arranged in a mesh pattern in plan view;
a field plate trench (42) formed in the semiconductor layer (12), the field plate trench (42) being surrounded by the gate trench (14) in plan view and being separated from the gate trench (14);
an insulation layer (26) formed on the semiconductor layer (12);
a gate electrode (28) arranged in the gate trench (14), the gate electrode (28) including an upper surface (28A) covered by the insulation layer (26) and a bottom surface (28B) opposite to the upper surface (28A);
a first field plate electrode (30) arranged in the gate trench (14) below the bottom surface (28B) of the gate electrode (28);
a second field plate electrode (50) arranged in the field plate trench (42), the second field plate electrode (50) including an upper surface (50A) covered by the insulation layer (26); and
a source electrode (38) formed on the insulation layer (26),
where the first field plate electrode (30) and the second field plate electrode (50) are electrically connected to the source electrode (38).

### [Clause 2]

The semiconductor device according to clause 1, further including:
a first contact plug (44) configured to couple the second field plate electrode (50) to the source electrode (38),
where the first contact plug (44) extends through the insulation layer (26) between the upper surface (50A) of the second field plate electrode (50) and the source electrode (38).

### [Clause 3]

The semiconductor device according to clause 2, where the first contact plug (44) overlaps the field plate trench (42) in plan view.

### [Clause 4]

The semiconductor device according to any one of clauses 1 to 3, where the field plate trench (42) is cross-shaped in plan view.

### [Clause 5]

The semiconductor device according to any one of clauses 1 to 3, where the field plate trench (42) is rectangular in plan view.

### [Clause 6]

The semiconductor device according to any one of clauses 1 to 3, where the field plate trench (42) includes
a first trench (302) extending in a first direction in plan view, and
a second trench (304) and a third trench (306) that are separated from the first trench (302) and extend in a second direction that is orthogonal to the first direction in plan view,
the first trench (302) extending between the second trench (304) and the third trench (306) in plan view.

### [Clause 7]

The semiconductor device according to any one of clauses 1 to 6, where
the semiconductor layer (12) includes a drift region (20) of a second conductivity type, a body region (22) of a first conductivity type formed on the drift region (20), and a source region (24) of the second conductivity type formed on the body region (22), and
the gate trench (14) and the field plate trench (42) extend through the source region (24) and the body region (22) to the drift region (20).

### [Clause 8]

The semiconductor device according to any one of clauses 1 to 7, further including:
a second contact plug (46) configured to couple the semiconductor layer (12) to the source electrode (38), where the second contact plug (46) extends through the insulation layer (26) between the semiconductor layer (12) and the source electrode (38).

### [Clause 9]

The semiconductor device according to clause 8, where the semiconductor layer (12) includes a contact region (48) of a first conductivity type, and the contact region (48) is in contact with the second contact plug (46).

### [Clause 10]

The semiconductor device according to clause 8 or 9, where the second contact plug (46) is arranged between the gate trench (14) and the field plate trench (42) in plan view.

### [Clause 11]

The semiconductor device according to any one of clauses 2 to 10, where
the second field plate electrode (50) includes a bottom surface (50B) opposite to the upper surface (50A), and
the semiconductor device further includes a third field plate electrode (202) arranged below the bottom surface (50B) of the second field plate electrode (50) in the field plate trench (42).

### [Clause 12]

The semiconductor device according to clause 11, where the first contact plug (44) is further configured to couple the third field plate electrode (202) to the source electrode (38) and extends through the second field plate electrode (50).

### [Clause 13]

The semiconductor device according to any one of clauses 1 to 12, where the semiconductor layer (12) includes mesh cells (M) surrounded by the gate trench (14), and the mesh cells (M) are each rectangular in plan view.

### [Clause 14]

The semiconductor device according to any one of clauses 1 to 12, where the semiconductor layer (12) includes mesh cells (M) surrounded by the gate trench (14), and the mesh cells (M) are each square in plan view.

### [Clause 15]

The semiconductor device according to clause 13 or 14, where the field plate trench (42) is one of multiple field plate trenches (42) respectively arranged in the mesh cells (M).

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

1. A semiconductor device, comprising:
a semiconductor layer;
a gate trench formed in the semiconductor layer and arranged in a mesh pattern in plan view;
a field plate trench formed in the semiconductor layer, the field plate trench being surrounded by the gate trench in plan view and being separated from the gate trench;
an insulation layer formed on the semiconductor layer;
a gate electrode arranged in the gate trench, the gate electrode including an upper surface covered by the insulation layer and a bottom surface opposite to the upper surface;
a first field plate electrode arranged in the gate trench below the bottom surface of the gate electrode;
a second field plate electrode arranged in the field plate trench, the second field plate electrode including an upper surface covered by the insulation layer; and
a source electrode formed on the insulation layer,
wherein the first field plate electrode and the second field plate electrode are electrically connected to the source electrode.

2. The semiconductor device according to claim 1, further comprising:
a first contact plug configured to couple the second field plate electrode to the source electrode,
wherein the first contact plug extends through the insulation layer between the upper surface of the second field plate electrode and the source electrode.

3. The semiconductor device according to claim 2, wherein the first contact plug overlaps the field plate trench in plan view.

4. The semiconductor device according to claim 1, wherein the field plate trench is cross-shaped in plan view.

5. The semiconductor device according to claim 1, wherein the field plate trench is rectangular in plan view.

6. The semiconductor device according to claim 1, wherein the field plate trench includes
a first trench extending in a first direction in plan view, and
a second trench and a third trench that are separated from the first trench and extend in a second direction that is orthogonal to the first direction in plan view, the first trench extending between the second trench and the third trench in plan view.

7. The semiconductor device according to claim 1, wherein
the semiconductor layer includes a drift region of a second conductivity type, a body region of a first conductivity type formed on the drift region, and a source region of the second conductivity type formed on the body region, and
the gate trench and the field plate trench extend through the source region and the body region to the drift region.

8. The semiconductor device according to claim 1, further comprising:
a second contact plug configured to couple the semiconductor layer to the source electrode, wherein the second contact plug extends through the insulation layer between the semiconductor layer and the source electrode.

9. The semiconductor device according to claim 8, wherein the semiconductor layer includes a contact region of a first conductivity type, and the contact region is in contact with the second contact plug.

10. The semiconductor device according to claim 8, wherein the second contact plug is arranged between the gate trench and the field plate trench in plan view.

11. The semiconductor device according to claim 2, wherein
the second field plate electrode includes a bottom surface opposite to the upper surface, and
the semiconductor device further comprises a third field plate electrode arranged below the bottom surface of the second field plate electrode in the field plate trench.

12. The semiconductor device according to claim 11, wherein the first contact plug is further configured to couple the third field plate electrode to the source electrode and extends through the second field plate electrode.

13. The semiconductor device according to claim 1, wherein the semiconductor layer includes mesh cells surrounded by the gate trench, and the mesh cells are each rectangular in plan view.

14. The semiconductor device according to claim 1, wherein the semiconductor layer includes mesh cells surrounded by the gate trench, and the mesh cells are each square in plan view.

15. The semiconductor device according to claim 13, wherein the field plate trench is one of multiple field plate trenches respectively arranged in the mesh cells.
